(19) United States
(12) Patent Application Publication
(10) Pub. No.: US 2015/0232987 A1
(43) Pub. Date: Aug. 20, 2015

(54) MANUFACTURING APPARATUS FOR DEPOSITING A MATERIAL AND A SOCKET FOR USE THEREIN

(71) Applicant: Hemlock Semiconductor Corporation, Hemlock, MI (US)

(72) Inventors: Matthew Deeg, East Lansing, MI (US); David Hillabrand, Midland, MI (US); William Larson, Midland, MI (US)

(21) Appl. No.: 14/413,972

(22) PCT Filed: Jul. 9, 2013
(86) PCT No.: PCT/US13/49743

§ 371 Date: Jan. 9, 2015

Related U.S. Application Data
(60) Provisional application No. 61/669,853, filed on Jul. 10, 2012.

(51) Int. Cl. C23C 16/44; C23C 16/34; C23C 16/26; C23C 16/32

(52) U.S. Cl. CPC C23C 16/4412; C23C 16/44; C23C 16/325; C23C 16/345; C23C 16/26; C23C 16/32

(57) ABSTRACT

A manufacturing apparatus deposits material on a carrier body. The manufacturing apparatus includes a housing defining a chamber. The housing defines an inlet for introducing a deposition composition, which comprises the material or a precursor thereof, into the chamber. The housing also defines an outlet through the housing for exhausting the deposition composition from the chamber. An electrode is disposed through the housing with the electrode at least partially disposed within the chamber. A socket has an exterior surface and is connected to the electrode within the chamber for receiving the carrier body. A release coating is disposed on the exterior surface of the socket for promoting separation of the socket from the carrier body, and the material deposited thereon, to harvest the carrier body.

### FIELD OF THE INVENTION

The present invention relates to a manufacturing apparatus for depositing a material on a carrier body. More specifically, the present invention relates to a socket supporting the carrier body within the manufacturing apparatus.

### BACKGROUND OF THE INVENTION

Manufacturing apparatuses for depositing material on a carrier body are known in the art. A conventional manufacturing apparatus includes a socket disposed at an end of the carrier body for coupling the carrier body to an electrode, which is within the conventional manufacturing apparatus. However, as the material is deposited on the carrier body, the material may also be deposited on the socket. For example, the material may be deposited directly on the socket. Alternatively, as the material is deposited on the carrier body, the material may grow and expand to encompass a portion of the socket.

Once a desired amount of material is deposited on the carrier body, the carrier body is harvested by removing it from the conventional manufacturing apparatus. Subsequently, the socket must be separated from the carrier body and, more specifically, the socket must be separated from the material deposited on the carrier body. Typically, the socket is separated from the carrier body and the deposited material by striking the deposited material near to or on the socket to fracture the deposited material. The process of striking the deposited material to remove it is very time consuming and costly. Additionally, even after fracturing, some of the deposited material remains on the socket. The deposited material on the socket is subjected to more aggressive processes to separate the deposited material and the socket. Unfortunately, the aggressive processes reduce the purity of the deposited material separated from the socket thereby reducing the value of the deposited material on the socket. Therefore, there remains a need to separate the deposited material from the socket without reducing the purity of the deposited material to preserve the value of the deposited material.

### SUMMARY OF THE INVENTION AND ADVANTAGES

A manufacturing apparatus deposits a material on a carrier body. The manufacturing apparatus includes a housing, which defines a chamber. The housing defines an inlet for introducing a deposition composition, which comprises the material or a precursor thereof, into the chamber. The housing also defines an outlet through the housing for exhausting the deposition composition from the chamber. An electrode is disposed through the housing with the electrode at least partially disposed within the chamber. A socket has an exterior surface and is connected to the electrode within the chamber for receiving the carrier body. A release coating is disposed on the exterior surface of the socket for promoting separation of the socket from the carrier body, and the material deposited thereon, to harvest the carrier body. Therefore, the material that may be deposited directly on the socket does not have to be subjected to additional separation processes to separate the deposited material from the socket thereby maintaining a purity of the material.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a cross-sectional view of a manufacturing apparatus for depositing a material on a carrier body including an electrode with the manufacturing apparatus including a jar and a base plate;

FIG. 2 is an enlarged view of a portion of the manufacturing apparatus showing the jar adjacent the base plate;

FIG. 3 is a perspective view of an electrode used in the manufacturing apparatus;

FIG. 4 is a cross-sectional view of a portion of the electrode taken along line 4-4 in FIG. 3 with a socket coupled to the electrode; and

FIG. 5 is a cross-sectional view of an alternative embodiment of the socket coupled to a carrier body.

### DETAILED DESCRIPTION OF THE INVENTION

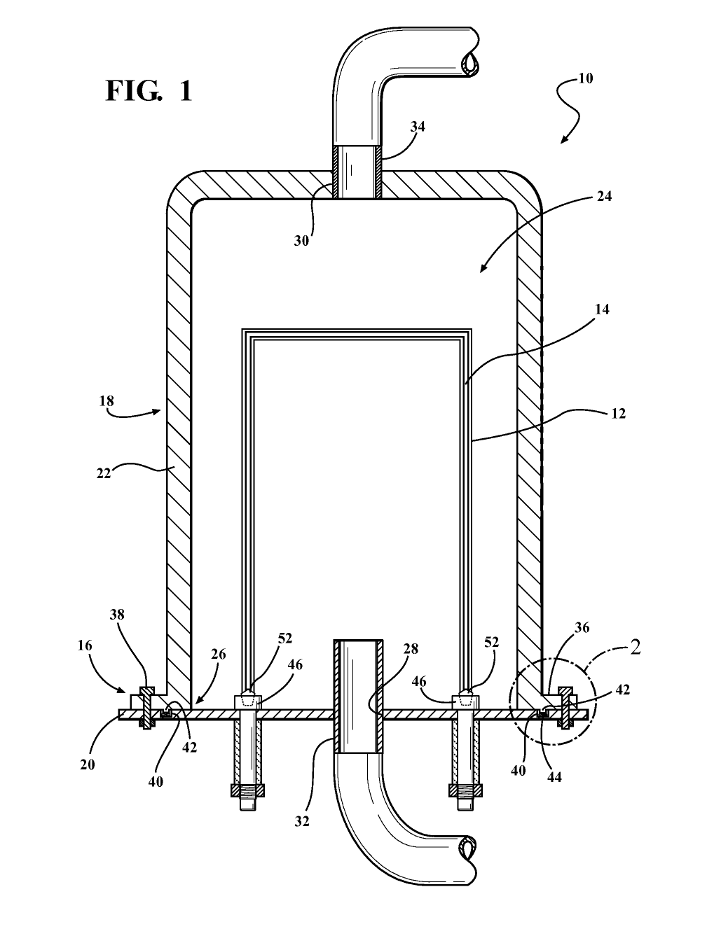

Referring to the Figures, wherein like numerals indicate like or corresponding parts throughout the several views, a manufacturing apparatus 10 for deposition of a material 12 on a carrier body 14 is shown. Said differently, during operation of the manufacturing apparatus 10, the material 12 is deposited on a carrier body 14. For example, the manufacturing apparatus 10 may be a chemical vapor deposition reactor, such as a Siemens type chemical vapor deposition reactor, for depositing silicon on the carrier body 14 to produce high purity polycrystalline silicon. As is known with the Siemens Method, the carrier body 14 may have a substantially U-shaped configuration, as shown in FIG. 1. However, it is to be appreciated that the carrier body 14 may have configurations other than the U-shaped configuration. Additionally, when the material 12 to be deposited is silicon, the carrier body 14 is typically a silicon slim rod comprising high purity silicon. The silicon is deposited on the silicon slim rod for producing high purity polycrystalline silicon.

With reference to FIG. 1, the manufacturing apparatus 10 comprises a housing 16. The housing 16 includes a jar 18 and a base plate 20. The jar 18 is coupled to the base plate 20 for forming the housing 16. The jar 18 of the housing 16 has at least one wall 22 with the wall 22 typically presenting a cylindrical configuration of the housing 16. However, it is to be appreciated that the jar 18 of the housing 16 may have configurations other than cylindrical, such as a cubed configuration. The housing 16 defines a chamber 24. More specifically, the jar 18 of the housing 16 has an interior that is hollow, such that the wall 22 of the jar 18 defines the chamber 24. The jar 18 has an end 26 that is open for allowing access to the chamber 24. The base plate 20 is coupled to the end 26 of the jar 18 that is open for covering the end 26 of the jar 18 and to seal the chamber 24.

The housing 16 defines an inlet 28 for introducing a deposition composition, which comprises the material 12 to be deposited or a precursor thereof, into the chamber 24. Similarly, the housing 16 may define an outlet 30 for allowing the deposition composition, or a reaction byproduct thereof, to be exhausted from the chamber 24. It is to be appreciated that the inlet 28 and/or the outlet 30 may be defined by either the jar 18 or the base plate 20 of the housing 16. Typically, an inlet pipe 32 is connected to the inlet 28 for delivering the deposition composition to the chamber 24 and an exhaust pipe 34 is connected to the outlet 30 for removing the deposition composition, or a reaction byproduct thereof, from the chamber 24.

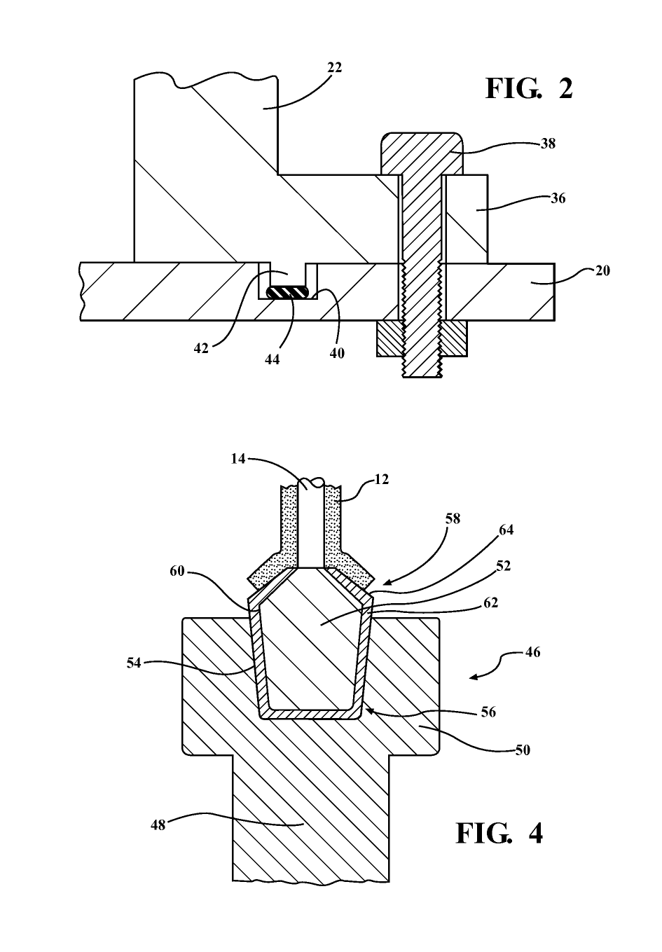

With reference to FIG. 2, the housing 16 may include a flange 36, which extends from the wall 22 of the housing 16. More specifically, the flange 36 extends transversely from the wall 22 of the housing 16. Typically, the flange 36 is parallel with the base plate 20 when the base plate 20 is coupled to the housing 16. A fastener 38, such as a bolt, may be used to secure the flange 36 of the housing 16 to the base plate 20.

The base plate 20 may define a groove 40. The groove 40 is defined about a periphery of the base plate 20. Additionally, the flange 36 of the housing 16 may have a finger 42 extending from the flange 36 for engaging the groove 40 of the base plate 20. The engagement of the finger 42 of the flange 36 with the groove 40 of the base plate 20 ensures that the base plate 20 and the housing 16 are properly aligned when coupling the housing 16 to the base plate 20. Generally, the mechanical interaction between the flange 36 and the base plate 20 is insufficient to prevent the deposition composition from escaping the chamber 24. Additionally, the mechanical interaction between the flange 36 and the base plate 20 is typically insufficient to prevent impurities external to the chamber 24, such as impurities in the ambient atmosphere outside the chamber 24, from entering the chamber 24. Therefore, the manufacturing apparatus 10 may further comprise a gasket 44 disposed between the base plate 20 and the jar 18 for sealing the chamber 24 between the jar 18 and the base plate 20. Additionally, the mechanical interaction between the finger 42 of the flange 36 with the groove 40 of the base plate 20 prevents the jar 18 from being laterally displaced as pressure increases within the chamber 24.

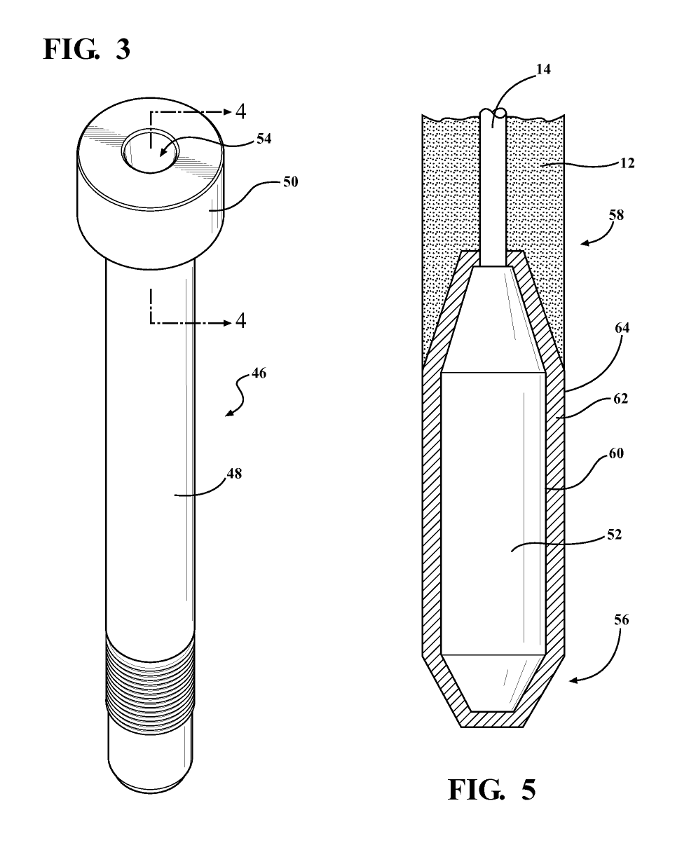

Referring again to FIG. 1, the manufacturing apparatus 10 includes an electrode 46 disposed through the housing 16. The electrode 46 is at least partially disposed within the chamber 24. For example, the electrode 46 is typically disposed through the base plate 20 with a portion of the electrode 46 supporting the carrier body 14 within the chamber 24. In one embodiment shown in FIG. 3, the electrode 46 includes a shaft 48 and a head 50 disposed at an end of the shaft 48. In such an embodiment, the head 50 is disposed within the chamber 24 for supporting the carrier body 14.

With reference to FIGS. 1 and 4, a socket 52 is connected to the electrode 46 within the chamber 24 for receiving the carrier body 14. Said differently, the socket 52 separates the carrier body 14 from the electrode 46. It is to be appreciated that the socket 52 may also be referred to as a chuck or a poly chuck by those skilled in the art. As best shown in FIG. 4, the electrode 46, and in particular the head 50 of the electrode 46, may define a cup 54 for receiving the socket 52. As such, the socket 52 may be at least partially disposed within the cup 54 to connect the socket 52 to the electrode 46.

Typically, the electrode 46 comprises an electrically conductive material 12 such as copper, silver, nickel, Inconel, gold, and combinations thereof. The electrode 46 is heated within the chamber 24 by passing an electric current through the electrode 46. Typically, the socket 52 comprises graphite because graphite is rigid enough to securely mount the carrier body 14 to the electrode 46 and is electrically conductive for conducting the electric current from the electrode 46 into the carrier body 14.

As a result of passing the electric current from the electrode 46 to the carrier body 14 via the socket 52, the carrier body 14 is heated to a deposition temperature by a process known as Joule heating. Heating the carrier body 46 to the deposition temperature generally facilitates thermal decomposition of the deposition composition. As alluded to above, the deposition composition comprises the material 12 to be deposited on the carrier body 14 or a precursor thereof. Therefore, the thermal decomposition of the deposition composition results in the material 12 being deposited on the heated carrier body 14. For example, when the material 12 to be deposited is silicon, the deposition composition may comprise a halosilane, such as a chlorosilane or a bromosilane. However, it is to be appreciated that the deposition composition may comprise other precursors, especially silicon containing molecules such as silane, silicon tetrachloride, tribromosilane, and trichlorosilane. It is also to be appreciated that the manufacturing apparatus 10 can be used to deposit material 12s other than silicon on the carrier body 14.

As introduced above, the socket 52 is heated by the passage of the electric current and may be heated to the deposition temperature. As such, the material 12 may also be deposited directly on the socket 52. Alternatively, as the material 12 is deposited on the carrier body 14 and grows in size, the material 12 may migrate onto the socket 52. Once a sufficient amount of the material 12 is deposited on the carrier body 14, the carrier body 14 is harvested from the manufacturing apparatus 10 by removing the carrier body 14 from the manufacturing apparatus 10. Typically, the deposition of the material 12 on the socket 52 and/or the carrier body 14 results in the socket 52 being adhered to the carrier body 14 by the material 12. Said differently, the material 12 deposited either directly on the socket 52 and/or the material 12 that grows onto the socket 52 from the carrier body 14 prevents the socket 52 from being separated from the carrier body 14. The socket 52 must be separated from the carrier body 14 and/or the material 12 to harvest the material 12. Additionally, the material 12 that is deposited directly on the socket 52 must also be separated from the socket 52.

Generally, the socket 52 has a first end 56 and a second end 58 with an exterior surface 60 between the first and second ends 56, 58. Generally, the first end 56 is connected to the electrode 46 and the second end 58 received the carrier body 14. Although not required, typically, the ends 56, 58 of the socket 52 are tapered to facilitate separation of the carrier body 14, and the material 12 deposited thereon, from the socket 52 once the carrier body 14 is harvested from the manufacturing apparatus 10. The socket 52 is also tapered to focus the electrical current into the carrier body 14.

To facilitate separation of the socket 52 from either the material 12 directly on the socket 52 itself or the carrier body 14, a release coating 62 is disposed on the exterior surface 60 of the socket 52. The release coating 62 promotes separation of the socket 52 from the material 12. Said differently, the release coating 62 promotes release of the material 12 deposited directly on the socket 52 itself or on the carrier body 14 near the socket 52. As such, the release coating 62 promotes separation of the socket 52 from the carrier body 14, and the material 12 deposited thereon, to allow the carrier body 14 to be harvested. Therefore, because the release coating 62 promotes release of the socket 52 from the carrier body 14, the socket 52 can be easily separated from the carrier body 14 after deposition of the material 12 on the carrier body 14. As such, the material 12 deposited on the carrier body 14 and/or the socket 52 does not have to go through additional separation processes, which may contaminate the material 12. Preventing contamination of the material 12 maintains a high purity of the material 12. Maintaining the high purity of the material 12, especially when the material 12 is silicon, means the material 12 is more valuable for sale to an end 26 user.

Generally, the material 12 is separated from the socket 52 by fracturing the material 12. The fracturing may occur by physically striking the material 12 to break it off the socket 52 in chunks. The release coating 62 is selected based on an initial crystal growth structure of the release coating 62 on the socket 52 to create a weak point thereby allowing the material 12 to be easily separated from the socket 52. The release coating 62 is selected such that the initial crystal growth of the release coating 62 is different than the crystal growth structure of the material 12 deposited on the carrier body 14. The different crystal growth structures create the weak point the material 12 deposited can be separated from the release coating 62. Typically, the release coating 62 is selected from the group of silicon carbide, silicon nitride, pyrolytic carbon, graphite silicon carbide, silicon dioxide, tantalum carbide, niobium carbide, and combinations thereof. More typically, the release coating 62 is pyrolytic carbon.

Additionally, the release coating 62 provides a finished surface 64 that is smoother than the exterior surface 60 of the socket 52. By providing the smoother surface, there is less surface area for the material 12 to adhere to on the socket 52, which promotes release of the material 12 from the socket 52. The finished surface 64 of the release coating 62 has a surface roughness RA value typically of from about 1 to about 100, more typically of from about 25 to about 50, and even more typically of from about 30 to 40 microns. It is to be appreciated that a surface area of the socket 52 may be reduced in other ways besides providing the finished surface 64 that is smoother than the exterior surface 60 of the socket 52. For example, a length of the socket 52 may be increased while decreasing a diameter of the socket 52 to reduce the surface area, as shown in FIG. 5. Additionally, the length of the socket may be reduced while increasing the diameter of the socket 52. It is also to be appreciated that the practice of varying the length and/or diameter of the socket 52 to reduce the surface area of the socket 52 may be employed in combination with the release coating 62.

While the release coating 62 promotes separation of the socket 52 from the material 12, the release coating 62 must still provide sufficient thermal conductivity to adequately heat the carrier body 14. As such, the release coating 62 has a thermal conductivity typically of from about 80 to 130, more typically of from about 90 to 125, and even more typically of from about 100 to 120 W/m K.

The thickness of the release coating 62 is dependent on the material 12 selected for the release coating 62. For example, when the release coating 62 is silicon carbide, the release coating 62 has a thickness of less than about 100 microns. When the release coating 62 is silicon nitride, tantalum carbide, or niobium carbide , the release coating 62 has a thickness of less than about 75 microns. When the release coating 62 is pyrolytic carbon, the release coating 62 has a thickness of less than about 50 microns. When the release coating 62 is graphite silicon carbide, the release coating 62 has a thickness of less than about 40 microns.

It is to be appreciated that the manufacturing apparatus 10 may include multiple electrodes 46 and sockets 52 for supporting multiple carrier bodies or multiple ends of the carrier body 14 in the case of the U-shaped carrier body 14. For example, the manufacturing apparatus 10 may include a first electrode 46A with a first socket 52A connected to the first electrode 46A and a second electrode 46B with a second socket 52B connected to the second electrode 46B. The first and second electrodes 46A, 46B are mirror images of each other and are similar to the electrode 46 described above. Likewise, the first and second sockets 52A, 52B are mirror images of each other and are similar to the socket 52 described above.

A method of depositing the material 12 on the carrier body 14 will now be described. The method comprising the step of applying a release coating 62 to the exterior surface 60 of the socket 52 to promote release of the carrier body 14, and the material 12 deposited thereon, from the socket 52 after the material 12 is deposited on the carrier body 14. The step of applying the release coating 62 may be accomplished in various methods such as by CVD and CVR processes. The process selected is dependent on the material 12 used as the release coating 62. For example, the step of applying the release coating 62 may be further defined as subjecting the socket 52 to a low pressure/high temperature CVD process to deposit silicon carbide or a graphite silicon carbide mixture on the exterior surface 60 of the socket 52 as the release coating 62. Additionally, the step of applying the release coating 62 may be further defined as subjecting the socket 52 to an atmospheric pressure/high temperature CVD process to deposit silicon nitride on the exterior surface 60 of the socket 52 as the release coating 62. Further more, the step of applying the release coating 62 may be further defined as subjecting the socket 52 to a high temperature CVD process to deposit pyrolytic carbon on the exterior surface 60 of the socket 52 as the release coating 62. Alternatively, the step of applying the release coating 62 may be further defined as subjecting the socket 52 to a CVR process to deposit tantalum carbide or niobium carbide on the exterior surface 60 of the socket 52 as the release coating 62.

The method of depositing the material 12 on the carrier body 14 also comprises the steps of connecting the socket 52 to the electrode 46 within the chamber 24 and connecting the carrier body 14 to the socket 52 within the chamber 24. The chamber 24 is sealed and the deposition composition is introduced into the chamber 24. The carrier body 14 is heated within the chamber 24, which results on the material 12, such as silicon, being deposited on the heated carrier body 14. Once the material 12 is deposited on the carrier body 14, the carrier body 14 is harvested from the chamber 24. It is to be appreciated that the step of harvesting the carrier body 14 may be further defined as separating the socket 52 from the carrier body 14, and the material 12 deposited thereon. For example, the material 12 is removed from the socket 52 to free the socket 52 from the carrier body 14. The step of separating the socket 52 from the carrier body 14 may take place within the chamber 24, such that the socket 52 remains in the chamber 24 as the carrier body 14 is removed. Alternatively, the step of separating the socket 52 from the carrier body 14 may take place once the carrier body 14 is removed from the chamber 24 such that the socket 52 is removed from the chamber 24 with the carrier body 14.

Obviously, many modifications and variations of the present invention are possible in light of the above teachings. The foregoing invention has been described in accordance with the relevant legal standards; thus, the description is exemplary rather than limiting in nature. Variations and modifications to the disclosed embodiment may become apparent to those skilled in the art and do come within the scope of the invention. Accordingly, the scope of legal protection afforded this invention may only be determined by studying the following claims.

1-23. (canceled)

24. A manufacturing apparatus for deposition of a material on a carrier body, said apparatus comprising:
a housing defining a chamber;
an inlet defined by said housing for introducing a deposition composition, which comprises the material or a precursor thereof, into said chamber;
an outlet defined through said housing for exhausting the deposition composition from said chamber;
an electrode disposed through said housing with said electrode at least partially disposed within said chamber;
a socket having an exterior surface and connected to said electrode within said chamber for receiving the carrier body; and
a release coating disposed on said exterior surface of said socket for promoting separation of said socket from the carrier body, and the material deposited thereon, to harvest the carrier body.

25. A manufacturing apparatus as set forth in claim 24, wherein said socket comprise graphite.

26. A manufacturing apparatus as set forth in claim 25, wherein said release coating is pyrolytic carbon.

27. A manufacturing apparatus as set forth in claim 26, wherein the material deposited on the carrier body is silicon.

28. A manufacturing apparatus as set forth in claim 25, wherein said release coating is selected from the group of silicon carbide, silicon nitride, pyrolytic carbon, graphite silicon carbide, silicon dioxide, tantalum carbide, niobium carbide, and combinations thereof.

29. A manufacturing apparatus as set forth in claim 28, wherein said release coating has a thickness of from 40 to 100 microns.

30. A manufacturing apparatus as set forth in claim 29, wherein said release coating presents a finished surface of said socket having a surface roughness RA value of from 1 to 100 microns.

31. A manufacturing apparatus as set forth in claim 24, wherein said electrode further includes a shaft and a head with said head defining a cup and with said socket disposed within said cup to connected said socket to said electrode.

32. A manufacturing apparatus as set forth in claim 24, wherein said electrode is further defined as a first electrode and said socket is further defined as a first socket and said manufacturing apparatus further includes a second socket connected to a second electrode, which is disposed in chamber.

33. A socket for use with a manufacturing apparatus, which deposits a material on a carrier body, the manufacturing apparatus including a housing defining a chamber, an inlet defined through the housing for introducing a deposition composition, which comprises the material or a precursor thereof, into the chamber, an outlet defined through the housing for exhausting the deposition composition from the chamber; an electrode disposed through the housing with the electrode at least partially disposed within the chamber with said socket connected to the electrode within the chamber for receiving the carrier body, said socket comprising:
a release coating disposed on said exterior surface of said socket for promoting separation of said socket from the carrier body, and the material deposited thereon, to harvest the carrier body.

34. A socket as set forth in claim 33, the socket comprising graphite.

35. A socket as set forth in claim 34, wherein said release coating presents a finished surface of said socket having a surface roughness RA value of from 1 to 100 microns.

36. A socket as set forth in claim 34, wherein said release coating is selected from the group of silicon carbide, silicon nitride, pyrolytic carbon, graphite silicon carbide, silicon dioxide, tantalum carbide, niobium carbide, and combinations thereof.

37. A socket as set forth in claim 35, wherein said release coating is pyrolytic carbon.

38. A socket as set forth in claim 35, wherein said release coating has a thickness of from 40 to 100 microns.

39. A method of manufacturing a socket having a release coating with the socket for use with a manufacturing apparatus, which deposits a material on a carrier body, the manufacturing apparatus including a housing defining a chamber, an inlet defined through the housing for introducing a deposition composition, which comprises the material or a precursor thereof, into the chamber, an outlet defined through the housing for exhausting the deposition composition from the chamber; an electrode disposed through the housing with the electrode at least partially disposed within the chamber with the socket connected to the electrode within the chamber for receiving the carrier body, said method comprising:
of applying the release coating to an exterior surface of the socket for promoting separation of the socket from the carrier body, and the material deposited thereon, to harvest the carrier body.

40. A method as set forth in claim 39, wherein applying the release coating is further defined as subjecting the socket to a low pressure/high temperature CVD process to deposit silicon carbide or a graphite silicon carbide mixture on the exterior surface of the socket as the release coating.

41. A method as set forth in claim 39, wherein applying the release coating is further defined as subjecting the socket to an atmospheric pressure/high temperature CVD process to deposit silicon nitride on the exterior surface of the socket as the release coating.

42. A method as set forth in claim 39, wherein applying the release coating is further defined as subjecting the socket to a high temperature CVD process to deposit pyrolytic carbon on the exterior surface of the socket as the release coating.

43. A method as set forth in claim 39, wherein applying the release coating is further defined as subjecting the socket to a CVR process to deposit tantalum carbide or niobium carbide on the exterior surface of the socket as the release coating.
